(19) United States
(12) Patent Application Publication
(10) Pub. No.: US 2024/0162312 A1
(43) Pub. Date: May 16, 2024

(54) SEMICONDUCTOR DEVICE

(71) Applicant: Sumitomo Electric Industries, Ltd., Osaka (JP)

(72) Inventor: Ken KIKUCHI, Osaka-shi (JP)

(73) Assignee: Sumitomo Electric Industries, Ltd., Osaka (JP)

(21) Appl. No.: 18/244,435

(22) Filed: Sep. 11, 2023

(30) Foreign Application Priority Data
Nov. 11, 2022 (JP) 2022-180772

(51) Int. Cl. H01L 29/417

(52) U.S. Cl. CPC H01L 29/4175

(57) ABSTRACT

A semiconductor device includes a substrate, a metal layer provided under the substrate, a plurality of source electrodes provided on the substrate and including first source electrodes and second source electrodes, one or a plurality of first via wirings that overlap with one of the first source electrodes closest to ends of the source electrodes, penetrate through the substrate, and electrically connect the metal layer and the first source electrodes, and one or a plurality of second via wirings that overlap with one of the second source electrodes second closest to the ends of the source electrodes, penetrate through the substrate, and electrically connect the metal layer and the second source electrodes, wherein a first inductance between the one of the first source electrodes and the metal layer is larger than a second inductance between the one of the second source electrodes and the metal layer.

### CROSS REFERENCE TO RELATED APPLICATIONS

This application claims priority based on Japanese Patent Application No. 2022-180772 filed on Nov. 11, 2022, and the entire contents of the Japanese patent applications are incorporated herein by reference.

### FIELD

The present disclosure relates to a semiconductor device.

### BACKGROUND

It is known that, in a multifinger-type field effect transistor (FET) having a plurality of source electrodes, a plurality of gate electrodes and a plurality of drain electrodes, a plurality of via hole are connected to the source electrodes (for example, Patent Document 1: Japanese Patent Application Laid-Open No. 11-150127).

### SUMMARY

A semiconductor device according to the present disclosure includes a substrate; a metal layer provided under the substrate; a plurality of source electrodes provided on the substrate and including a pair of first source electrodes and a pair of second source electrodes, the pair of first source electrodes being closest to ends of the plurality of source electrodes arranged in a direction in which the plurality of source electrodes are arranged, the pair of second source electrodes being second closest to the ends of the plurality of source electrodes; one or a plurality of first via wirings that overlap with one of the pair of first source electrodes in a plan view, penetrate through the substrate, and electrically connect the metal layer and the one of the pair of first source electrodes; and one or a plurality of second via wirings that overlap with one of the pair of second source electrodes in the plan view, penetrate through the substrate, and electrically connect the metal layer and the one of the pair of second source electrodes; wherein a first inductance between the one of the pair of first source electrodes and the metal layer via the one or plurality of first via wirings is larger than a second inductance between the one of the pair of second source electrodes and the metal layer via the one or plurality of second

### BRIEF DESCRIPTION OF DRAWINGS

FIG. 1 is a plan view of a semiconductor device according to a first embodiment.

FIG. 2 is a cross-sectional view taken along line A-A of FIG. 1.

FIG. 3 is a plan view of a semiconductor device according to a first comparative example.

FIG. 4 is a plan view illustrating a virtual structure 1.

FIG. 5 is a circuit diagram illustrating an equivalent circuit of the virtual structure 1.

FIG. 6 is a plan view illustrating a virtual structure 2.

FIG. 7 is a circuit diagram illustrating an equivalent circuit of the virtual structure 2.

FIG. 8 is a plan view illustrating a virtual structure 3.

FIG. 9 is a plan view of a semiconductor device according to a second embodiment.

FIG. 10 is a plan view of a semiconductor device according to a third embodiment.

FIG. 11 is a plan view of a semiconductor device according to a fourth embodiment.

FIG. 12 is a plan view of a semiconductor device according to a fifth embodiment.

FIG. 13 is a plan view of a semiconductor device according to a sixth embodiment.

FIG. 14 is a plan view of a semiconductor device according to a seventh embodiment.

### DETAILED DESCRIPTION OF EMBODIMENTS

Source inductances may be different from each other between a source electrode closest to an end of the plurality of source electrodes and another source electrode. This may result in unstable high frequency operation.

The present disclosure has been made in view of the above problems, and an object of the present disclosure is to stabilize the operation of the semiconductor device.

### Details of Embodiments of the Present Disclosure

First, the contents of the embodiments of this disclosure are listed and explained.

(1) A semiconductor device according to the present disclosure includes a substrate; a metal layer provided under the substrate; a plurality of source electrodes provided on the substrate and including a pair of first source electrodes and a pair of second source electrodes, the pair of first source electrodes being closest to ends of the plurality of source electrodes arranged in a direction in which the plurality of source electrodes are arranged, the pair of second source electrodes being second closest to the ends of the plurality of source electrodes; one or a plurality of first via wirings that overlap with one of the pair of first source electrodes in a plan view, penetrate through the substrate, and electrically connect the metal layer and the one of the pair of first source electrodes; and one or a plurality of second via wirings that overlap with one of the pair of second source electrodes in the plan view, penetrate through the substrate, and electrically connect the metal layer and the one of the pair of second source electrodes; wherein a first inductance between the one of the pair of first source electrodes and the metal layer via the one or plurality of first via wirings is larger than a second inductance between the one of the pair of second source electrodes and the metal layer via the one or plurality of second via wirings. Thus, the operation of the semiconductor device can be stabilized.

(2) In the above (1), the one or plurality of first via wirings may be a plurality of first via wirings. The one or plurality of second via wirings may be a plurality of second via wirings. A first interval between the plurality of first via wirings adjacent to each other may be smaller than a second interval between the plurality of second via wirings adjacent to each other.

(3) In the above (2), a number of the plurality of first via wirings may be equal to or less than a number of the plurality of second via wirings. A first area in a plan view in which each of the plurality of first via wirings is in contact with one of the pair of first source electrodes may be equal to or less than a second area in the plan view in which each of the plurality of second via wirings is in contact with one of the pair of second source electrodes.

(4) In the above (1), a number of the one or plurality of first via wirings may be less than a number of the one or plurality of second via wirings.

(5) In the above (4), when the one or plurality of first via wirings are a plurality of first via wirings, and the one or plurality of second via wirings are a plurality of second via wirings, a first interval between the plurality of first via wirings adjacent to each other may be equal to or less than a second interval between the plurality of second via wirings adjacent to each other. A first area in a plan view in which each of the one or plurality of first via wirings is in contact with the one of the pair of first source electrodes may be equal to or less than a second area in the plan view in which each of the one or plurality of second via wirings is in contact with the one of the pair of second source electrodes.

(6) In the above (1), a first area in a plan view in which each of the one or plurality of first via wirings is in contact with the one of the pair of first source electrodes may be smaller than a second area in the plan view in which each of the one or plurality of second via wirings is in contact with the one of the pair of second source electrodes.

(7) In the above (6), a number of the one or plurality of first via wirings may be equal to or less than a number of the one or plurality of second via wirings. When the one or plurality of first via wirings are a plurality of first via wirings, and the one or plurality of second via wirings are a plurality of second via wirings, a first interval between the plurality of first via wirings adjacent to each other may be equal to or less than a second interval between the plurality of second via wirings adjacent to each other.

(8) In any one of the above (1) to (7), the plurality of source electrodes further may include a third source electrode which is third closest to the ends of the plurality of source electrodes. The semiconductor device further may include one or a plurality of third via wirings that overlap with the third source electrode in the plan view, penetrate through the substrate, and electrically connect the metal layer and the third source electrode. A third inductance between the third source electrode and the metal layer via the one or plurality of third via wirings may be smaller than the second inductance.

(9) In the above (1) or (8), when the one or plurality of first via wirings is a single first via wiring, the first inductance may be a self-inductance of the single first via wiring. When the one or plurality of first via wirings is a plurality of first via wirings, the first inductance may be a sum of an inductance obtained by combining self-inductances of the plurality of first via wirings and a mutual inductance between the plurality of first via wirings. When the one or plurality of second via wirings is a single second via wiring, the second inductance may be a self-inductance of the single second via wiring. When the one or plurality of second via wirings is a plurality of second via wirings, the second inductance may be a sum of an inductance obtained by combining self-inductances of the plurality of second via wirings and a mutual inductance between the plurality of second via wirings.

(10) In any one of the above (1) to (9), the semiconductor device further may include a plurality of gate electrodes provided on the substrate; and a plurality of drain electrodes provided on the substrate. Each of the plurality of gate electrodes may be sandwiched between one of the plurality of source electrodes and one of the plurality of drain electrodes.

Specific examples of the semiconductor device in accordance with embodiments of the present disclosure are described below with reference to the drawings. The present disclosure is not limited to these examples, but is indicated by the claims, which are intended to include all modifications within the meaning and scope of the claims.

### First Embodiment

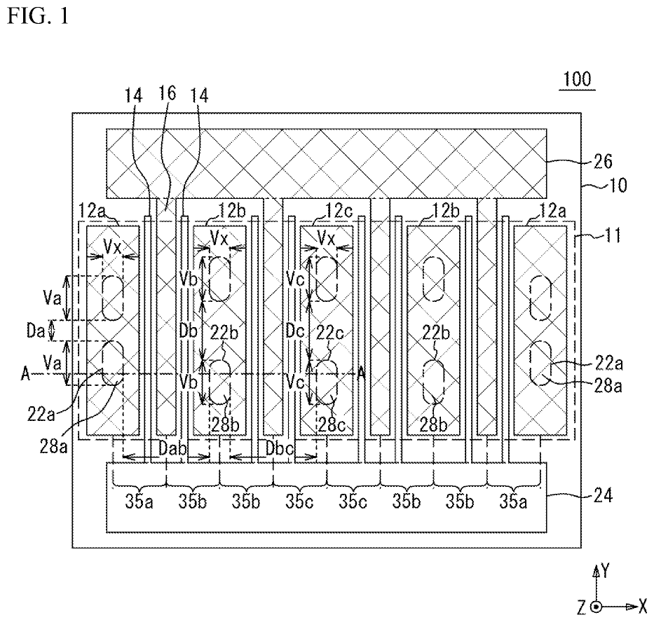

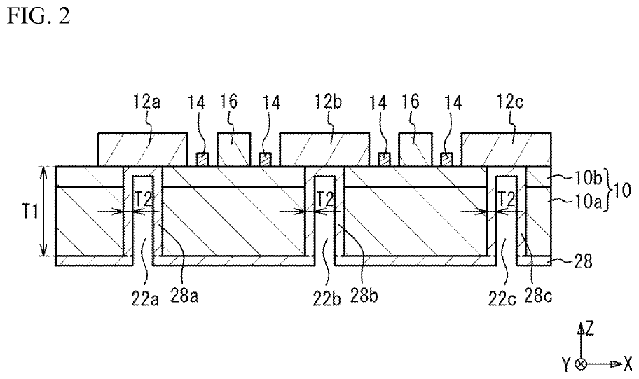

FIG. 1 is a plan view of a semiconductor device according to the first embodiment. FIG. 2 is a cross-sectional view taken along the line A-A of FIG. 1. A normal direction of an upper surface of a substrate 10 is a Z direction, an arrangement direction of source electrodes 12a to 12c, gate electrodes 14 and drain electrodes 16 is an X direction, and an extension direction of the source electrodes 12a to 12c, the gate electrodes 14 and the drain electrodes 16 is a Y direction. In the plan view of FIG. 1 and the like, the source electrodes 12a to 12c, the drain electrodes 16 and a drain bus bar 26 are cross-hatched.

As illustrated in FIGS. 1 and 2, in a semiconductor device 100 of the first embodiment, the substrate 10 includes a substrate 10a and a semiconductor layer 10b provided on the substrate 10a. An active region 11 is provided on the substrate 10. A region other than the active region 11 is an inactive region in which the semiconductor layer 10b is inactivated by ion implantation or the like. That is, the active region 11 is a region in which the semiconductor layer 10b in the substrate 10 is activated, and the inactive region is a region in which the semiconductor layer 10b is inactivated. A field effect transistor (FET) 35 is provided in the active region 11.

The plurality of source electrodes 12a to 12c (source fingers), the gate electrodes 14 (gate finger) and the drain electrodes 16 (drain finger) are provided on the active region 11. The source electrode 12a (first source electrode) is closest to an end (i.e., an end of the plurality of arrayed source electrodes 12a to 12c) of the plurality of source electrodes 12a to 12c in the X direction (the direction in which the source electrodes 12a to 12c are arranged). The source electrode 12b (second source electrode) is the second closest to the end in the X direction of the plurality of source electrodes 12a to 12c. The source electrode 12c (third source electrode) is the third closest to the end in the X direction of the plurality of source electrodes 12a to 12c.

In the X direction, the drain electrodes 16 and the source electrodes 12a to 12c are alternately provided one by one. The gate electrode 14 is provided between one of the plurality of source electrodes 12a to 12c and one of the plurality of drain electrodes 16. Thus, the source electrodes 12a to 12c and the drain electrodes 16 sandwiching the gate electrode 14 form individual unit FETs 35a to 35c, respectively. The unit FETs 35 a to 35c have source electrodes 12a to 12c, respectively. The unit FETs 35 a to 35c are arranged in the X direction. The number of unit FETs 35 a to 35c may be four or more.

A gate bus bar 24 and the drain bus bar 26 are provided on the inactive region on the upper surface of the substrate 10 and are extended in the X direction. Negative Y ends (i.e., −Y ends) of the plurality of gate electrodes 14 in the Y direction are connected to the gate bus bar 24. Positive ends (i.e., +Y ends) in the Y direction of the plurality of drain electrodes 16 are connected to the drain bus bar 26.

Via holes 22a to 22c penetrating through the substrate 10 are connected to the source electrodes 12a to 12c, respectively. A metal layer 28 is provided on a lower surface of the substrate 10. A reference potential such as a ground potential is supplied to the metal layer 28. Via wirings 28a (first via wiring), 28b (second via wiring), and 28c (third via wiring) are provided on side surfaces and upper surfaces of the via holes 22a, 22b, and 22c, respectively. That is, the via wirings 28a to 28c are provided on the substrate below the source electrodes 12a to 12c, respectively, and overlap with the source electrodes 12a to 12c in a plan view, respectively. The via wirings 28a to 28c penetrate through the substrate 10, and electrically connect and short-circuit the metal layer 28 and the source electrodes 12a to 12c, respectively. The via wirings 28a to 28c are the same metal layer as the metal layer 28 and are formed at the same time. Air gaps are provided in the via wirings 28a to 28c in the via hole 22a to 22c. Each of the air gaps is filled with a gas such as air. A conductor may be embedded in the air gaps of the via wirings 28a to 28c.

The via wirings 28a, the via wirings 28b and the via wirings 28c are arranged in the Y direction in the source electrode 12a, the source electrode 12b and the source electrode 12c, respectively. The planar shape of each of the via wirings 28a to 28c is, for example, an edge-rounded square shape. A major axis direction of the via wiring 28a to 28c is the Y direction, and a minor axis thereof is the X direction. The planar shape of the via wirings 28a to 28c may be a substantially elliptical shape, a substantially circular shape, or an elongated shape other than the edge-rounded square shape. The plane areas (i.e., areas of the regions in contact with the source electrodes 12a to 12c) of the via wirings 28a to 28c are substantially the same as each other. The regions where the via wirings 28a to 28c are connected to the source electrodes 12a to 12c are included within the source electrodes 12a to 12c. That is, the via wirings 28a to 28c are not provided on the upper surface of the substrate 10 outside the source electrodes 12a to 12c.

When the semiconductor device 100 is, for example, a nitride semiconductor device, the substrate 10a is, for example, an SiC substrate, a diamond substrate, a silicon substrate, a GaN substrate, or a sapphire substrate. The semiconductor layer 10b includes, for example, a nitride semiconductor layer such as a GaN layer, an AlGaN layer and/or an InGaN layer. When the semiconductor device 100 is a GaN HEMT (Gallium Nitride High Electron Mobility Transistor), the semiconductor layer 10b includes a GaN electron-transport layer and an AlGaN barrier layer provided on the GaN electron-transport layer. When the semiconductor device is, for example, a GaAs-based semiconductor device, the substrate 10a is, for example, a GaAs substrate. The semiconductor layer 10b includes, for example, an arsenide semiconductor layer such as a GaAs layer, an AlGaAs layer and/or an InGaAs layer.

Each of the source electrodes 12a to 12c and the drain electrodes 16 has, for example, an adhesion film (for example, a titanium film) provided on the substrate 10 and a metal film such as an aluminum film provided on the adhesion film. A wiring layer such as a gold layer may be provided on the aluminum film. Each of the gate electrodes 14 has, for example, an adhesion film (for example, a nickel film) provided on the substrate 10 and a metal film such as a gold film provided on the adhesion film. The metal layer 28 and the via wirings 28a to 28c are, for example, gold layers.

Widths Vx of the via wirings 28a to 28c in the X direction are substantially the same as each other and are, for example, 20 μm. Widths Va, Vb and Vc of the via wirings 28a to 28c in the Y direction are substantially the same as each other and are, for example, 50 μm. An interval Db between the via wirings 28b in the Y direction and an interval Dc between the via wirings 28c in the Y direction are substantially the same as each other, and are, for example, 50 μm. An interval Da between the via wirings 28a in the Y direction is smaller than the intervals Db and Dc, and is, for example, 20 μm. An interval Dab between the via wirings 28a and 28b in the X direction and an interval Dbc between the via wirings 28b and 28c in the X direction are, for example, 100 μm. A thickness T1 of the substrate 10 is, for example, 100 μm, and thicknesses T2 of the via wiring 28a, 28b and 28c are, for example, 5 μm.

### First Comparative Example

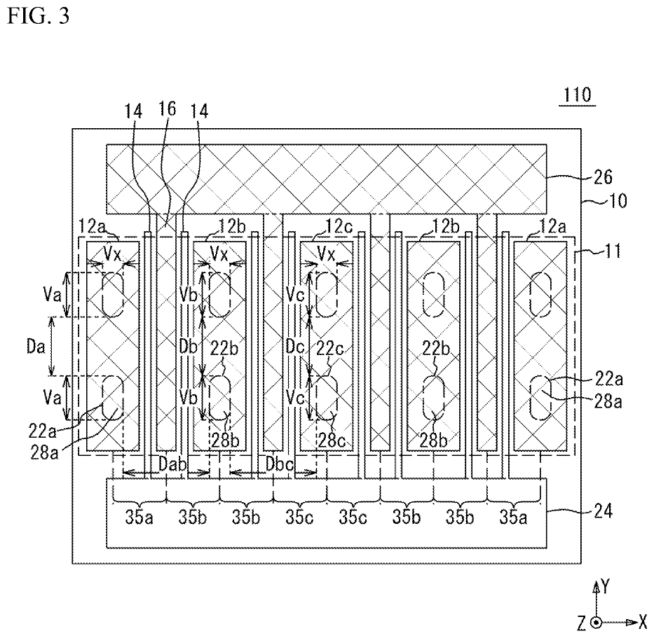

FIG. 3 is a plan view of a semiconductor device according to a first comparative example. As illustrated in FIG. 3, in a semiconductor device 110 of the first comparative example, the interval Da between the via wirings 28a is substantially equal to the intervals Db and Dc. Other configurations of the first comparative example are the same as those of the first embodiment, and description thereof is omitted.

[Virtual Structure 1]

The problem of the first comparative example will be explained using a virtual structure. The following discussion on the virtual structure is based on a condition that the widths of the source electrodes 12a to 12c in the Y direction are sufficiently smaller than the wavelength of the high frequency signal. When the widths of the source electrodes 12a to 12c in the Y direction are approximately equal to the wavelength of the high frequency signal, the source electrodes 12a to 12c are expressed as a distributed constant, and the expression of a lumped constant becomes difficult. For example, when the semiconductor device 100 is used for a power amplifier (power amplifier) for wireless communication, the operating band is any one of a band from 0.5 GHz to 10 GHz. When the frequency of the high frequency signal (for example, the center frequency of the operating band of the amplifier) is 10 GHz or less, the above condition is satisfied if the widths of the source electrodes 12a to 12c in the Y direction are several 100 μm or less.

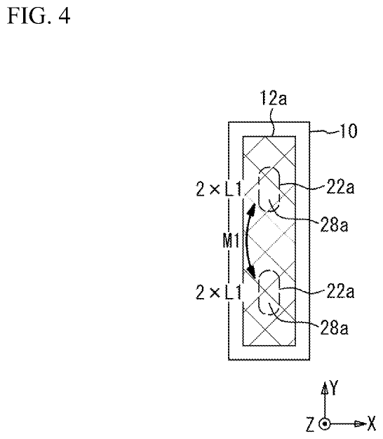

FIG. 4 is a plan view illustrating a virtual structure 1. As illustrated in FIG. 4, the source electrode 12a is connected to a ground via the via wiring 28a provided in the via hole 22a. The via wiring 28a has a self-inductance of 2×L1. Since two via wirings 28a are magnetically coupled to each other, a mutual inductance M1 is generated.

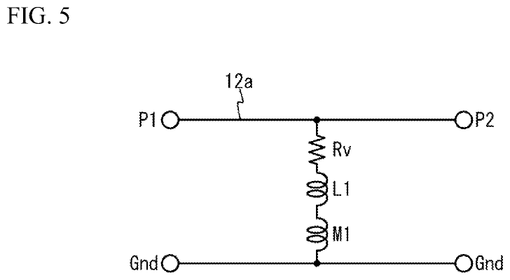

FIG. 5 is a circuit diagram illustrating an equivalent circuit of the virtual structure 1. As illustrated in FIG. 5, a line between ports P1 and P2 (corresponding to the source electrodes 12a) is connected to a ground Gnd via a resistor Rv, the self-inductance L1, and the mutual inductance M1 of the via wiring 28a. Since the self-inductances 2×L1 of the via wirings 28a are connected in parallel, the self-inductance L1 becomes an inductance L1 obtained by combining the inductances 2×L1.

[Virtual Structure 2]

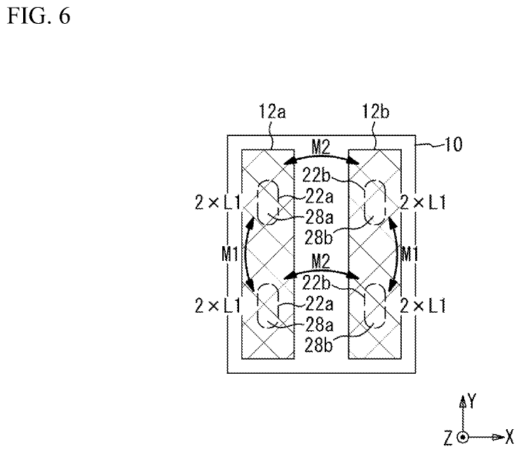

FIG. 6 is a plan view illustrating the virtual structure 2. As illustrated in FIG. 6, each of the source electrode 12a and the source electrode 12b is connected to the ground via the via wirings 28a and 28b provided respectively in the via holes 22a and 22b. Each of the via wirings 28a and 28b has self-inductances of 2×L1. Similarly to the via wiring 28a, the two via wirings 28b are magnetically coupled to each other, so that the mutual inductance M1 is generated. Further, the via wirings 28a and 28b are magnetically coupled. As a result, a mutual inductance M2 is generated.

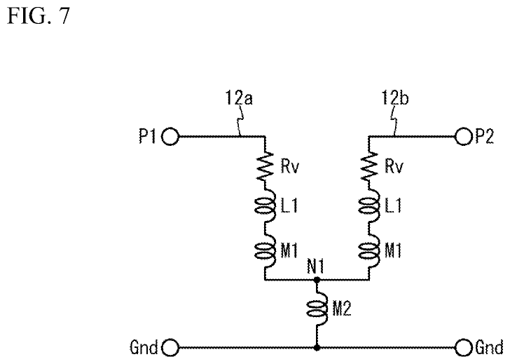

FIG. 7 is a circuit diagram illustrating an equivalent circuit of the virtual structure 2. As illustrated in FIG. 7, a line of the port P1 (corresponding to the source electrodes 12a) is connected to a node N1 via the resistor Rv, the self-inductance L1, and the mutual inductance M1. A line of the port P2 (corresponding to the source electrodes 12b) is connected to the node N1 via the resistor Rv, the self-inductance L1, and the mutual inductance M1. The node N1 is connected to the ground via the mutual inductance M2.

Thus, the source inductance of the virtual structure 2 is larger by the mutual inductance M2 than that of the virtual structure 1. Each inductance is simulated using an electromagnetic field analysis method. In the simulation, the widths Vx of the via wirings 28a to 28c were 20 μm, the widths Va, Vb and Vc were 50 μm, the intervals Da, Db and Dc between the via wirings 28a to 28c were 50 μm, the interval Dab between the via wirings 28a and 28b was 100 μm, the thickness T1 of the substrate 10 was 100 μm, the thicknesses T2 of the via wirings 28a, 28b and 28c were 5 μm, and the substrate 10 was the SiC substrate. At this time, L1=15 pH, M1=5 pH, and M2=5 pH were satisfied.

[Virtual Structure 3]

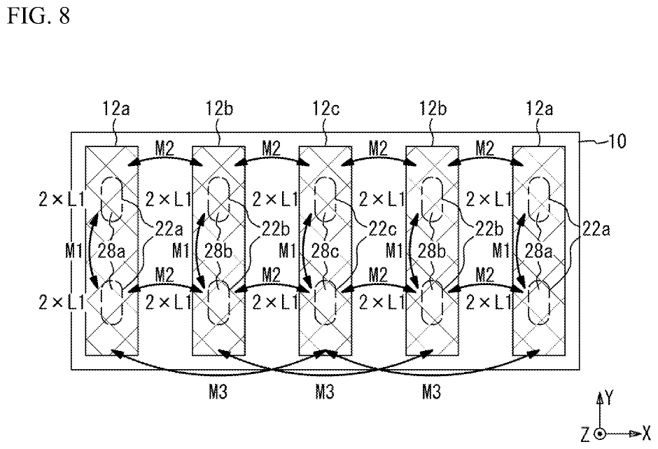

FIG. 8 is a plan view illustrating the virtual structure 3. As illustrated in FIG. 8, the source electrodes 12a to 12c are arranged in the same manner as in FIG. 3. The mutual inductance with the via wiring of the adjacent source electrode is denoted by M2, and the mutual inductance with the via wiring of the second nearest source electrode is denoted by M3. The mutual inductance M3 is smaller than the mutual inductance M2.

A mutual inductance contributing to a source inductance Lsa of the source electrode 12a includes the mutual inductance M2 with the via wiring 28b of the source electrode 12b adjacent to the source electrode 12a, and the mutual inductance M3 with the via wiring 28c of the source electrode 12c located two neighbors from the source electrode 12a. A mutual inductance contributing to a source inductance Lsb of the source electrode 12b includes the mutual inductance M2 with the via wiring 28a of the adjacent source electrode 12a, the mutual inductance M2 with the via wiring 28c of the adjacent source electrode 12c, and the mutual inductance M3 with the via wiring 28b of another source electrode 12b located two neighbors from the source electrode 12b. A mutual inductance contributing to a source inductance Lsc of the source electrode 12c includes two mutual inductances M2 with the via wirings 28b of two adjacent source electrodes 12b, and two mutual inductances M3 with the via wirings 28a of two source electrodes 12a located two neighbors from the source electrode 12c.

As described above, the mutual inductance contributing to the source inductance Lsa of the source electrode 12a is the single mutual inductance M2 and the single mutual inductance M3. The mutual inductance contributing to the source inductance Lsb of the source electrode 12b is the two mutual inductances M2 and the single mutual inductance M3. The mutual inductance contributing to the source inductance Lsc of the source electrode 12c includes the two mutual inductances M2 and the two mutual inductances M3. These mutual inductances are connected in series with the ground. The above-described relationship of inductance is briefly described as follows:

Lsa=L1+M1+M2+M3

Lsb=L1+M1+2*M2+M3

Lsc=L1+M1+2*M2+2*M3

The magnitude relationship of the source inductance is Lsa<Lsb<Lsc. Since the mutual inductance M3 is smaller than M2, “Lsb−Lsa>Lsc−Lsb” is satisfied.

As described above, in the first comparative example, the source inductance Lsa of the unit FET 35a, the source inductance Lsb of the unit FET 35b, and the source inductance Lsc of the unit FET 35c are different from each other. Therefore, when the semiconductor device 110 is used as an amplifier and the high frequency signal is input to the gate electrodes 14, the operation of the unit FETs 35 a to 35c becomes non-uniform. This causes the gain of the amplifier to decrease.

According to the first embodiment, the interval Da between the via wirings 28a is smaller than the intervals Db and Dc. Thus, a mutual inductance M1a between the via wirings 28a becomes larger than the mutual inductance M1 between the via wirings 28b and the mutual inductance M1 between the via wirings 28c. That is, the following relationship is satisfied.

Lsa=L1+M1a+M2+M3

On the other hand, the source inductance Lsb is as follows.

Lsb=L1+M1+2*M2+M3

Thus, by setting “M1a-M1” to about M2, Lsa and Lsb can be made substantially the same. Therefore, a difference between Lsa and Lsb in the first embodiment can be made smaller than a difference between Lsa and Lsb in the first comparative example. On the other hand, a difference between Lsb and Lsc in the first embodiment is not so large. Therefore, the operation of the unit FETs 35a to 35c can be made uniform.

### Second Embodiment

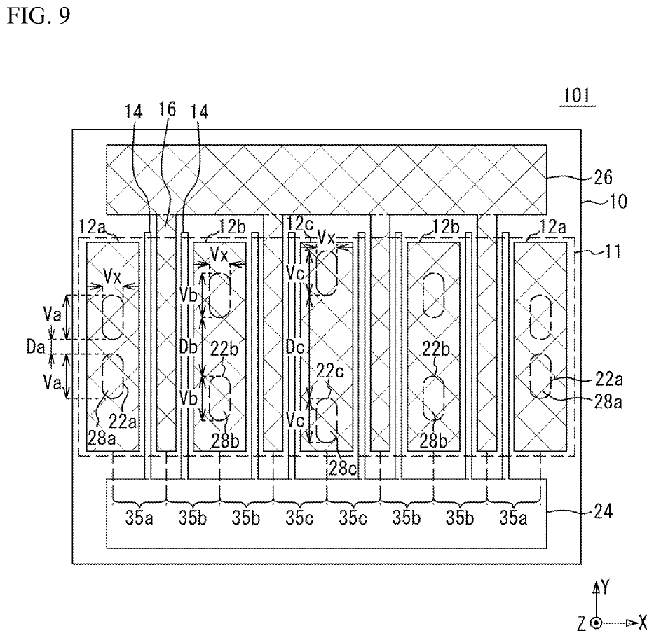

FIG. 9 is a plan view of a semiconductor device according to a second embodiment. As illustrated in FIG. 9, in a semiconductor device 101 of the second embodiment, the interval Da between the via wirings 28a in the Y direction is smaller than the interval Db between the via wirings 28b in the Y direction, and the interval Db is smaller than the interval Dc between the via wirings 28c in the Y direction. The widths Va, Vb and Vc of the via wirings 28a to 28c in the Y direction are the same as each other. Other configurations of the second embodiment are the same as those of the first embodiment, and description thereof is omitted.

The relationship between the inductances in the second embodiment is briefly described as follows:

Lsa=L1+M1a+M2+M3

Lsb=L1+M1b+2*M2+M3

Lsc=L1+M1c+2*M2+2*M3

Here, since Da<Db<Dc is satisfied, M1a>M1b>M1c is satisfied. “M1a-M1b” is set to about M2, and “M1b-M1c” is set to about M3. This allows the difference between Lsa and Lsb and the difference between Lsb and Lsc to be smaller in the second embodiment than in the first comparative example. Thus, the operation of the unit FETs 35a to 35c can be made more uniform.

### Third Embodiment

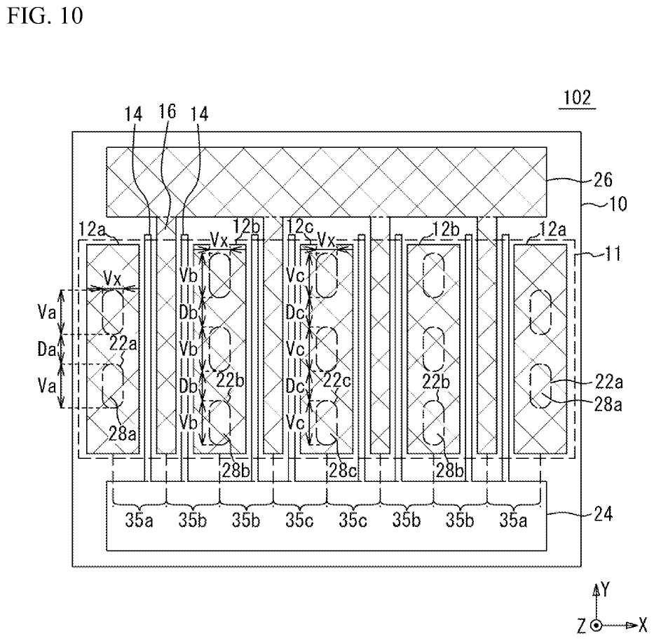

FIG. 10 is a plan view of a semiconductor device according to a third embodiment. As illustrated in FIG. 10, in a semiconductor device 102 of the third embodiment, two via wirings 28a are connected to a single source electrode 12a. Three via wirings 28b are connected to a single source electrode 12b. Three via wirings 28c are connected to a single source electrode 12c. The intervals Da, Db and Dc are substantially the same as each other, and the widths Va, Vb and Vc are substantially the same as each other. Other configurations of the third embodiment are the same as those of the first embodiment, and description thereof is omitted.

The relationship between the inductances in the third embodiment is briefly described as follows:

Lsa=L1a+M1+M2+M3

Lsb=L1b+M1+2*M2+M3

Lsc=L1c+M1+2*M2+2*M3

The number of via wirings 28a connected to the single source electrode 12a is 2, the number of via wirings 28b connected to the single source electrode 12b is 3, and the number of via wirings 28c connected to the single source electrode 12c is 3. Therefore, L1b=L1c≤2*L1a/3 is satisfied. Therefore, L1a>L1b=L1c is satisfied. As a result, the difference between Lsa and Lsb can be smaller in the third embodiment than in the first comparative example. Therefore, the operation of the unit FETs 35a to 35c can be made uniform.

### Fourth Embodiment

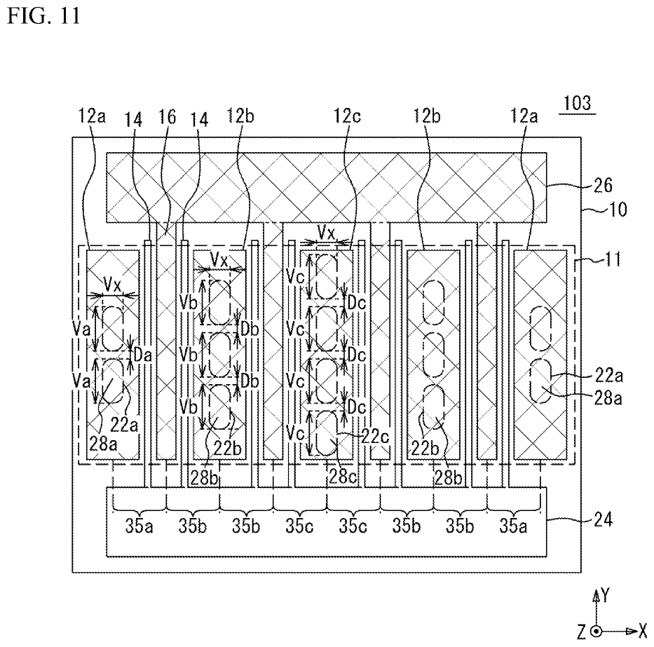

FIG. 11 is a plan view of a semiconductor device according to a fourth embodiment. As illustrated in FIG. 11, in a semiconductor device 103 of the fourth embodiment, two via wirings 28a are connected to the single source electrode 12a. Three via wirings 28b are connected to the single source electrode 12b. Four via wirings 28c are connected to the single source electrode 12c. The intervals Da, Db and Dc are substantially the same as each other, and the widths Va, Vb and Vc are substantially the same as each other. Other configurations of the fourth embodiment are the same as those of the first embodiment, and description thereof is omitted.

The relationship between the inductances in the fourth embodiment is briefly described as follows:

Lsa=L1a+M1+M2+M3

Lsb=L1b+M1+2*M2+M3

Lsc=L1c+M1+2*M2+2*M3

From the number of via wirings 28a, 28b and 28c, L1b≈2*L1a/3 and L1c≈L1a/2 are obtained. Therefore, L1a>L1b>L1c is satisfied. Thus, the difference between Lsa and Lsb and the difference between Lsb and Lsc can be smaller in the fourth embodiment than in the first comparative example. Therefore, the operation of the unit FETs 35a to 35c can be made uniform.

### Fifth Embodiment

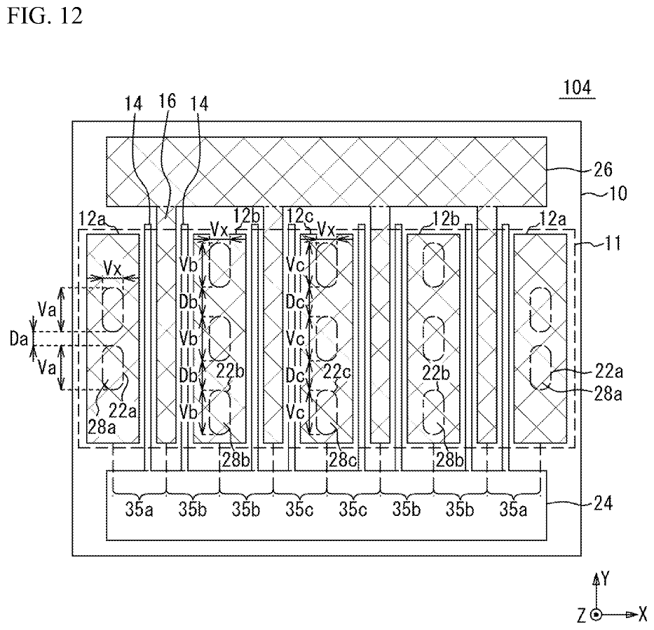

FIG. 12 is a plan view of a semiconductor device according to a fifth embodiment. As illustrated in FIG. 12, in a semiconductor device 104 of the fifth embodiment, two via wirings 28a are connected to the single source electrode 12a. Three via wirings 28b are connected to the single source electrode 12b. Three via wirings 28c are connected to the single source electrode 12c. The interval Da is smaller than the intervals Db and Dc. The widths Va, Vb and Vc are substantially the same as each other. Other configurations of the fifth embodiment are the same as those of the first embodiment, and description thereof is omitted.

The relationship between the inductances in the fifth embodiment is briefly described as follows:

Lsa=L1a+M1a+M2+M3

Lsb=L1b+M1b+2*M2+M3

Lsc=L1c+M1c+2*M2+2*M3

The number of via wirings 28a is smaller than the number of via wirings 28b and 28c. Therefore, L1a>L1b≈L1c is satisfied. Since Da<Db=Dc is satisfied, M1a>M1b≈M1c is satisfied. Thus, the difference between Lsa and Lsb can be made smaller in the fifth embodiment than in the first comparative example. Therefore, the operation of the unit FETs 35a to 35c can be made uniform.

### Sixth Embodiment

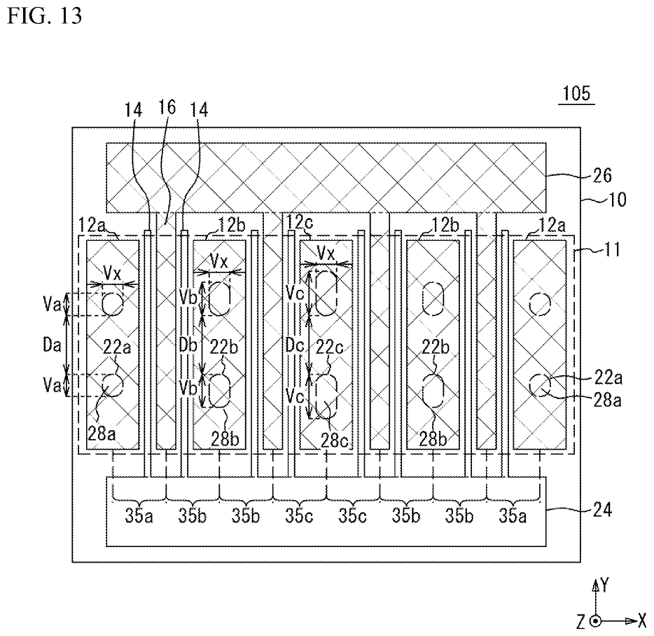

FIG. 13 is a plan view of a semiconductor device according to a sixth embodiment. As illustrated in FIG. 13, in a semiconductor device 105 of the sixth embodiment, the width Va of the via wiring 28a in the Y direction is smaller than the width Vb of the via wiring 28b in the Y direction, and the width Vb is smaller than the width Vc of the via wiring 28c in the Y direction. Other configurations of the sixth embodiment are the same as those of the first embodiment, and description thereof is omitted.

The relationship between the inductances in the sixth embodiment is briefly described as follows:

Lsa=L1a+M1+M2+M3

Lsb=L1b+M1+2*M2+M3

Lsc=L1c+M1+2*M2+2*M3

Since Va<Vb<Vc is satisfied, L1a>L1b>L1c is satisfied. Thus, the difference between Lsa and Lsb and the difference between Lsb and Lsc can be made smaller in the sixth embodiment than in the first comparative example. Therefore, the operation of the unit FETs 35a to 35c can be made uniform.

### Seventh Embodiment

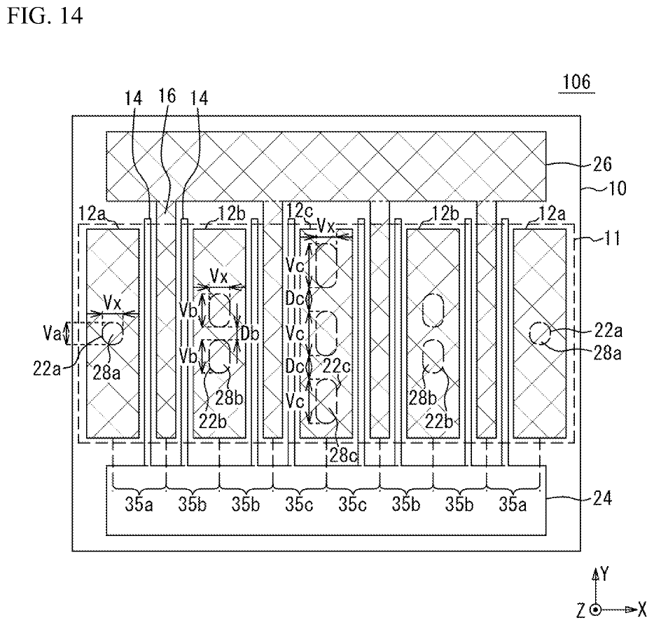

FIG. 14 is a plan view of a semiconductor device according to a seventh embodiment. As illustrated in FIG. 14, in a semiconductor device 106 of the seventh embodiment, the single via wiring 28a is connected to the single source electrode 12a. Two via wirings 28b are connected to the single source electrode 12b. Three via wirings 28c are connected to the single source electrode 12c. The width Va of the via wiring 28a in the Y direction is smaller than the width Vb of the via wiring 28b in the Y direction, and the width Vb is smaller than the width Vc of the via wiring 28c in the Y direction. The interval Db of the via wiring 28b in the Y direction is smaller than the interval Dc of the via wiring 28c in the Y direction. Other configurations of the seventh embodiment are the same as those of the first embodiment, and description thereof is omitted.

The relationship between the inductances in the seventh embodiment is briefly described as follows:

Lsa=L1a+M2+M3

Lsb=L1b+M1b+2*M2+M3

Lsc=L1c+M1c+2*M2+2*M3

Since the number of via wirings 28a connected to the single source electrode 12a is 1, Lsa does not include M1. Since Db<Dc is satisfied, M1b>M1c is satisfied. Since Va<Vb<Vc is satisfied, L1a>L1b>L1c is satisfied. Thus, the difference between Lsa and Lsb and the difference between Lsb and Lsc can be made smaller in the seventh embodiment than in the first comparative example. Therefore, the operation of the unit FETs 35a to 35c can be made uniform.

### Summary of First to Seventh Embodiments

In the first to the seventh embodiments, a first inductance between one of the source electrodes 12a and the metal layer 28 via one or the plurality of via wirings 28a is larger than a second inductance between one of the source electrodes 12b and the metal layer 28 via one or the plurality of via wirings 28b. Thus, the difference between the source inductance Lsa of the source electrode 12a and the source inductance Lsb of the source electrode 12b in the first to the seventh embodiments can be made smaller than those in the first comparative example. Therefore, the operation of the unit FETs 35a to 35c can be made uniform. The gains of the semiconductor devices 100 to 106 can be improved.

As in the second, the fourth, the fifth and the seventh embodiments, a third inductance between one of the source electrodes 12c and the metal layer 28 via one or the plurality of via wirings 28c is smaller than the second inductance between one of the source electrodes 12b and the metal layer 28 via one or the plurality of via wirings 28b. Thus, the difference between the source inductance Lsb of the source electrode 12b and the source inductance Lsc of the source electrode 12c in the second, the fourth, the fifth and the seventh embodiments can be made smaller than those in the first comparative example. Therefore, the operation of the unit FETs 35a to 35c can be made uniform. The gain of the semiconductor device can be further improved.

The first inductance is, for example, 1.05 times or more and 1.1 times or more of the second inductance. The first inductance is, for example, twice or less of the second inductance. The difference between the source inductance Lsa and the source inductance Lsb in the first to the seventh embodiments is smaller than the difference between the source inductance Lsa and the source inductance Lsb in the first comparative example in which the number of the via wiring 28a and the number of the via wiring 28b are the same and Va=Vb and Da=Db are satisfied. As a result, the operation of the unit FETs 35a to 35c in the first to the seventh embodiments can be made more uniform than in the first comparative example.

The second inductance is, for example, 1.01 times or more and 1.05 times or more of the third inductance. The second inductance is, for example, 1.5 times or less of the third inductance. The difference between the source inductances Lsb and Lsc in the second, the fourth, the fifth and the seventh embodiments is smaller than the difference between the source inductances Lsb and Lsc in the first comparative example. As a result, the operation of the unit FETs 35a to 35c in the second, the fourth, the fifth and the seventh embodiments can be made more uniform than in the first comparative example.

When the single via wiring 28a is connected to the single source electrode 12a, the first inductance is the self-inductance of the single via wiring 28a. When the plurality of via wirings 28a are connected to the single source electrode 12a, the first inductance is an inductance including the inductance L1 obtained by combining the self-inductances of the via wirings 28a, and the mutual inductance M1 between the plurality of via wirings 28a.

When the single via wiring 28b is connected to the single source electrode 12b, the second inductance is the self-inductance of the single via wiring 28b. When the plurality of via wirings 28b are connected to the single source electrode 12b, the second inductance is an inductance including the inductance L1 obtained by combining the self-inductances of the via wirings 28b, and the mutual inductance M1 between the plurality of via wirings 28b.

When the single via wiring 28c is connected to the single source electrode 12c, the third inductance is the self-inductance of the single via wiring 28c. When the plurality of via wirings 28c are connected to the single source electrode 12c, the third inductance is an inductance including the inductance L1 obtained by combining the self-inductances of the via wirings 28c, and the mutual inductance M1 between the plurality of via wirings 28c.

Thus, the difference of the mutual inductance M2 between source inductances Lsa and Lsb can be compensated by using the self-inductance L1 and the mutual inductance M1.

As in the first, the second and the fifth embodiments, the interval Da between the adjacent via wirings 28a is made smaller than the interval Db between the adjacent via wirings 28b. Thus, the mutual inductance M1 in the source inductance Lsa can be made larger than the mutual inductance M1 in the source inductance Lsb. Therefore, the difference between the source inductance Lsa and the source inductance Lsb can be reduced.

At this time, a first number of via wirings 28a connected to the single source electrode 12a is made equal to or smaller than a second number of via wirings 28b connected to the single source electrode 12b. A first area in a plan view in which each of the via wirings 28a is in contact with the source electrode 12a is made to be equal to or smaller than a second area in the plan view in which each of the via wirings 28b is in contact with the source electrode 12b. Thus, a sum of the self-inductance L1 and the mutual inductance M1 in the source inductance Lsa can be made larger than a sum of the self-inductance L1 and the mutual inductance M1 in the source inductance Lsb.

For example, the interval Da is 0.95 times or less, or 0.9 times or less of the interval Db. Further, the interval Dais, for example, 0.1 times or more of the interval Db. In the case where the difference between the source inductance Lsb and the source inductance Lsc is reduced, the interval Db is smaller than the interval Dc and is 0.99 times or less, or 0.98 times or less of the interval Dc. Further, the interval Db is, for example, 0.1 times or more of the interval Dc. When the number of via wirings 28a (28b or 28c) connected to the single source electrode 12a (12b or 12c) is three or more, the number of intervals between the adjacent via wirings 28a (28b or 28c) is plural. When the values of the plurality of intervals are different from each other, the interval Da (Db or Dc) is an average of the values of the plurality of intervals.

As in the third, the fourth, the fifth and the seventh embodiments, the number of via wirings 28a is smaller than the number of via wirings 28b. Thereby, the self-inductance L1 in the source inductance Lsa can be made larger than the self-inductance L1 in the source inductance Lsb. Therefore, the difference between the source inductance Lsa and the source inductance Lsb can be reduced.

At this time, the interval Da between the plurality of via wirings 28a adjacent to each other is made equal to or smaller than the interval Db between the plurality of via wirings 28b adjacent to each other. The first area in the plan view in which each of the via wirings 28a is in contact with the source electrode 12a is made to be equal to or smaller than the second area in the plan view in which each of the via wirings 28b is in contact with the source electrode 12b. Thus, the sum of the self-inductance L1 and the mutual inductance M1 in the source inductance Lsa can be made larger than the sum of the self-inductance L1 and the mutual inductance M1 in the source inductance Lsb.

For example, when the difference between the source inductance Lsb and the source inductance Lsc is reduced, the number of the via wirings 28b is made smaller than the number of the via wirings 28c.

As in the sixth and the seventh embodiments, the first area in the plan view in which each of the via wirings 28a is in contact with the source electrode 12a is made smaller than the second area in the plan view in which each of the via wirings 28b is in contact with the source electrode 12b. Thereby, the sum of the self-inductance L1 and the mutual inductance M1 in the source inductance Lsa can be made larger than the sum of the self-inductance L1 and the mutual inductance M1 in the source inductance Lsb.

At this time, the interval Da between the plurality of via wirings 28a adjacent to each other is made equal to or smaller than the interval Db between the plurality of via wirings 28b adjacent to each other. The first number of via wirings 28a connected to the single source electrode 12a is set to be equal to or less than the second number of via wirings 28b connected to the single source electrode 12b. Thereby, the sum of the self-inductance L1 and the mutual inductance M1 in the source inductance Lsa can be made larger than the sum of the self-inductance L1 and the mutual inductance M1 in the source inductance Lsb.

For example, the first area is 0.95 times or less, or 0.9 times or less of the second area. The first area is, for example, 0.1 times or more of the second area. When the difference between the source inductance Lsb and the source inductance Lsc is reduced, the second area is smaller than a third area in a plan view in which the via wiring 28c is in contact with the source electrode 12c, and is 0.99 times or less or 0.95 times or less of the third area. The second area is, for example, 0.1 times or more of the third area. When the number of via wirings 28a (28b or 28c) connected to the single source electrode 12a (12b or 12c) is plural, and the areas of the plurality of via wirings 28a (28b or 28c) are different from each other, the first area (second area or third area) is the average of the areas of the plurality of via wirings 28a (28b or 28c).

The embodiments disclosed here should be considered illustrative in all respects and not restrictive. The present disclosure is not limited to the specific embodiments described above, but various variations and changes are possible within the scope of the gist of the present disclosure as described in the claims.

What is claimed is:

1. A semiconductor device comprising:
a substrate;
a metal layer provided under the substrate;
a plurality of source electrodes provided on the substrate and including a pair of first source electrodes and a pair of second source electrodes, the pair of first source electrodes being closest to ends of the plurality of source electrodes arranged in a direction in which the plurality of source electrodes are arranged, the pair of second source electrodes being second closest to the ends of the plurality of source electrodes;
one or a plurality of first via wirings that overlap with one of the pair of first source electrodes in a plan view, penetrate through the substrate, and electrically connect the metal layer and the one of the pair of first source electrodes; and
one or a plurality of second via wirings that overlap with one of the pair of second source electrodes in the plan view, penetrate through the substrate, and electrically connect the metal layer and the one of the pair of second source electrodes;
wherein a first inductance between the one of the pair of first source electrodes and the metal layer via the one or plurality of first via wirings is larger than a second inductance between the one of the pair of second source electrodes and the metal layer via the one or plurality of second via wirings.

2. The semiconductor device according to claim 1, wherein
the one or plurality of first via wirings are a plurality of first via wirings,
the one or plurality of second via wirings are a plurality of second via wirings, and
a first interval between the plurality of first via wirings adjacent to each other is smaller than a second interval between the plurality of second via wirings adjacent to each other.

3. The semiconductor device according to claim 2, wherein
a number of the plurality of first via wirings is equal to or less than a number of the plurality of second via wirings, and
a first area in a plan view in which each of the plurality of first via wirings is in contact with one of the pair of first source electrodes is equal to or less than a second area in the plan view in which each of the plurality of second via wirings is in contact with one of the pair of second source electrodes.

4. The semiconductor device according to claim 1, wherein
a number of the one or plurality of first via wirings is less than a number of the one or plurality of second via wirings.

5. The semiconductor device according to claim 4,
when the one or plurality of first via wirings are a plurality of first via wirings, and the one or plurality of second via wirings are a plurality of second via wirings, a first interval between the plurality of first via wirings adjacent to each other is equal to or less than a second interval between the plurality of second via wirings adjacent to each other, and
a first area in a plan view in which each of the one or plurality of first via wirings is in contact with the one of the pair of first source electrodes is equal to or less than a second area in the plan view in which each of the one or plurality of second via wirings is in contact with the one of the pair of second source electrodes.

6. The semiconductor device according to claim 1, wherein
a first area in a plan view in which each of the one or plurality of first via wirings is in contact with the one of the pair of first source electrodes is smaller than a second area in the plan view in which each of the one or plurality of second via wirings is in contact with the one of the pair of second source electrodes.

7. The semiconductor device according to claim 6, wherein
a number of the one or plurality of first via wirings is equal to or less than a number of the one or plurality of second via wirings, and
when the one or plurality of first via wirings are a plurality of first via wirings, and the one or plurality of second via wirings are a plurality of second via wirings, a first interval between the plurality of first via wirings adjacent to each other is equal to or less than a second interval between the plurality of second via wirings adjacent to each other.

8. The semiconductor device according to claim 1, wherein
the plurality of source electrodes further includes a third source electrode which is third closest to the ends of the plurality of source electrodes,
the semiconductor device further includes one or a plurality of third via wirings that overlap with the third source electrode in the plan view, penetrate through the substrate, and electrically connect the metal layer and the third source electrode, and
a third inductance between the third source electrode and the metal layer via the one or plurality of third via wirings is smaller than the second inductance.

9. The semiconductor device according to claim 1, wherein
when the one or plurality of first via wirings is a single first via wiring, the first inductance is a self-inductance of the single first via wiring,
when the one or plurality of first via wirings is a plurality of first via wirings, the first inductance is a sum of an inductance obtained by combining self-inductances of the plurality of first via wirings and a mutual inductance between the plurality of first via wirings,
when the one or plurality of second via wirings is a single second via wiring, the second inductance is a self-inductance of the single second via wiring, and
when the one or plurality of second via wirings is a plurality of second via wirings, the second inductance is a sum of an inductance obtained by combining self-inductances of the plurality of second via wirings and a mutual inductance between the plurality of second via wirings.

10. The semiconductor device according to claim 1, further comprising:
a plurality of gate electrodes provided on the substrate; and
a plurality of drain electrodes provided on the substrate;
wherein each of the plurality of gate electrodes is sandwiched between one of the plurality of source electrodes and one of the plurality of drain electrodes.
